(19) United States
(12) Patent Application Publication
(10) Pub. No.: US 2024/0183953 A1
(43) Pub. Date: Jun. 6, 2024

(54) TDC APPARATUS, DISTANCE MEASURING APPARATUS AND CORRECTION METHOD

(71) Applicant: HOKUYO AUTOMATIC CO., LTD., Osaka-shi, Osaka (JP)

(72) Inventors: Kunihiro YASUDA, Osaka-shi (JP); Toshihiro KAMITANI, Osaka-shi (JP)

(73) Assignee: HOKUYO AUTOMATIC CO., LTD., Osaka-shi, Osaka (JP)

(21) Appl. No.: 18/561,025

(22) PCT Filed: May 11, 2022
(86) PCT No.: PCT/JP2022/019893

§ 371 Date: Nov. 15, 2023

(30) Foreign Application Priority Data
May 17, 2021 (JP) 2021-083390

(51) Int. Cl. G01S 7/4865; G01S 7/497; G01S 17/10; G04F 10/00; H03K 5/14

(52) U.S. Cl. CPC G01S 7/4865; G01S 7/497; G01S 17/10; H03K 5/14; G04F 10/005

(57) ABSTRACT

A TDC apparatus includes a TDC circuit having a delay circuit including a plurality of stages of delay elements configured to sequentially delay a measurement signal and a plurality of storage elements configured to respectively hold outputs of the plurality of stages of delay elements in response to a measurement clock input thereto; an edge detection unit that detects at least a rising edge of the measurement signal based on switching of the outputs of the plurality of storage elements; and a delay amount correction unit configured to output a delay time of the measurement signal whose delay amount has been corrected by adding or subtracting a correction delay amount to or from a delay amount corresponding to the detection stage of the delay element in a delay conversion table relating to the detection stage of the delay element and a delay amount of the plurality of delay elements.

### TECHNICAL FIELD

The present invention relates to a TDC apparatus, a distance measuring apparatus and a correction method.

### BACKGROUND ART

Distance measuring apparatuses for measuring the distance to an object use a TDC (time-to-digital converter) circuit to detect the flight time of light from emission to reception of reflected light. TDC circuits digitize time information. These TDC circuits often utilize a method that uses delay elements and flip-flops. In such TDC circuits, the delay amount of the delay elements varies depending on factors such as manufacturing conditions of the semiconductor devices and temperature change during operation (so-called PVT (Process Voltage Temperature) variation). The measurement accuracy of the TDC circuit is affected when the delay amount of the delay elements varies. In view of this, the distance measuring apparatus performs a calibration operation that involves inputting a calibration signal to the TDC circuit at a timing at which the distance measurement operation is not performed, and estimating the delay amount of each delay element in the TDC circuit.

Patent Document 1 discloses a technique for calibrating the variation in the delay time of the delay elements so as to operate normally with respect to PVT variation. The method described in Patent Document 1 involves adjusting the amount of bias current related to the delay elements to achieve a target delay time.

### LIST OF RELATED ART DOCUMENTS

### Patent Document

Patent Document 1: Japanese Patent Laid-Open Publication No. 2012-114716

### SUMMARY OF INVENTION

### Problems to be Solved by the Invention

Incidentally, the calibration operation performed by the distance measuring apparatus is desirably completed in the shortest possible time, since the distance measurement operation cannot be performed when the calibration operation is being performed. Thus, in the calibration operation, an extremely large number of pulses (calibration signals) need to be input to the TDC circuit in a shorter period of time than during the measurement operation. When pulses are continuously input to the TDC circuit in a short period of time, a voltage drop by which the supply voltage value of the circuit falls below a predetermined voltage value becomes larger than during the measurement operation. That is, the voltage drop of the circuit during the calibration operation differs from the voltage drop during the measurement operation. This difference in voltage drop causes the delay amount of the delay element during the calibration operation to differ from the delay amount during the measurement operation. As a result, even if the delay amount of the delay element is estimated in the calibration operation, there is a risk of not being able to perform proper distance measurement.

In view of this, an example object of the invention is to provide a TDC apparatus, a distance measuring apparatus and a correction method that are able to improve measurement accuracy during a distance measurement operation for measuring the distance to an object while reducing the influence of variation in a voltage drop amount of a supply voltage of a TDC circuit during a calibration operation.

### Means for Solving the Problems

(1) In order to achieve the above object, a TDC apparatus according to an example aspect of the invention includes: a TDC circuit having a delay circuit including a plurality of stages of delay elements configured to sequentially delay a measurement signal and a plurality of storage elements provided in correspondence with the plurality of stages of delay elements and configured to respectively hold outputs of the plurality of stages of delay elements in response to a measurement clock input thereto; an edge detection unit configured to detect a detection stage of a delay element, among the plurality of delay elements, that detects at least a rising edge of the measurement signal, based on switching of the outputs of the plurality of storage elements; and a delay amount correction unit configured to output a delay time of the measurement signal whose delay amount has been corrected by adding or subtracting a correction delay amount to or from a delay amount corresponding to the detection stage of the delay element in a delay conversion table relating to the detection stage of the delay element and a delay amount of the plurality of delay elements.

This TDC apparatus is able to improve measurement accuracy during the distance measurement operation for measuring the distance to an object while reducing the influence of variation in the voltage drop amount of the supply voltage of the TDC circuit during the calibration operation.

(2) The TDC apparatus of (1) above may further include a delay conversion table generation unit configured to input a calibration signal whose period differs from the measurement clock to the delay circuit of the TDC circuit, and generate the delay conversion table relating to the detection stage of a delay element, among the plurality of delay elements, that detects a rising edge of the calibration signal and the delay amount of the plurality of delay elements.

In this case, a delay conversion table can be generated during calibration.

(3) In the TDC apparatus of (2) above, the delay amount of the delay conversion table generation unit may be a cumulative delay amount of the delay elements up to each detection stage from an initial stage of the plurality of stages of delay elements.

In this case, the cumulative delay amount of the delay elements from an initial stage of the plurality of stages of delay elements to each detection stage can be acquired from the delay conversion table.

(4) The delay amount correction unit of the TDC apparatus of (3) above may correct the delay amount by adding, to a cumulative delay amount tᵢ corresponding to the delay element of an ith stage, a correction delay amount t_{ci} calculated by the following equation:

$${t}_{ci} = \{ \begin{matrix}{t}_{i} \times ( - \frac{{x}_{c}}{{x}_{max} + {x}_{c}} ) + {t}_{offset} , & i < {x}_{max} \\ {t}_{offset} - {h}_{i} \times \frac{{t}_{offset}}{{\sum }_{0}^{{x}_{c}} {h}_{i}} , & i = {x}_{max} \\ {t}_{c ( i - 1 )} - {h}_{i} \times \frac{{t}_{offset}}{{\sum }_{0}^{{x}_{c}} {h}_{i}} , & i > {x}_{max}\end{matrix} , {t}_{offset} = \frac{N \times {x}_{c}}{{x}_{max} + {x}_{c}} \qquad [ Equation 1 ]$$

where hᵢ is a detection count in which the rise of the calibration signal is detected by the delay element of the ith stage, Xₘₐₓ is a maximum stage number of the delay elements in the delay conversion table, X_{C} is a predetermined correction stage number, and N is a total detection count in which the rise of the calibration signal is detected by the delay element of each stage.

In this case, the correction delay amount can be calculated.

(5) Also, a distance measuring apparatus according to an example aspect of the invention includes the TDC apparatus of any one of (1) to (4) above, a light projecting unit configured to emit measurement light in synchronization with the measurement clock; a light receiving unit configured to receive reflected light of the measurement light reflected by an object and output a measurement signal related to the reflected light to the TDC apparatus; and a distance calculation unit configured to calculate a distance to the object from a time difference between the measurement light and the reflected light after a delay amount is corrected in the TDC apparatus.

The distance measuring apparatus is able to improve measurement accuracy during the distance measurement operation.

(6) The distance measuring apparatus of (5) above may further include at least one of a light deflection unit configured to cause the measurement light emitted from the light projecting unit to be deflected in a predetermined direction and a light scanning unit configured to cause the measurement light to be scanned in a predetermined direction.

In this case, the measurement light can be deflected in a predetermined direction or the measurement light can be scanned in a predetermined direction.

(7) Also, a correction method according to an example aspect of the invention is a correction method in a TDC apparatus including a TDC circuit having a delay circuit including a plurality of stages of delay elements configured to sequentially delay a measurement signal and a plurality of storage elements provided in correspondence with the plurality of stages of delay elements and configured to respectively hold outputs of the plurality of stages of delay elements in response to a measurement clock input thereto, the correction method including: detecting a detection stage of a delay element, among the plurality of delay elements, that detects at least a rising edge of the measurement signal, based on switching of the outputs of the plurality of storage elements; and outputting a delay time of the measurement signal whose delay amount has been corrected by adding or subtracting a correction delay amount to or from a delay amount corresponding to the detection stage of the delay element in a delay conversion table relating to the detection stage of the delay element and a delay amount of the plurality of delay elements.

This configuration enables measurement accuracy during the distance measurement operation for measuring the distance to an object to be improved while reducing the influence due to variation in the amount of voltage drop during the calibration operation.

### Advantageous Effects of the Invention

According to the invention, measurement accuracy during a distance measurement operation for measuring the distance to an object can be improved while reducing the influence due to variation in the amount of voltage drop during a calibration operation, for example.

### BRIEF DESCRIPTION OF THE DRAWINGS

FIG. 1 is a block diagram showing a configuration of a distance measuring apparatus according to an example embodiment.

FIG. 2 shows a TDC circuit.

FIG. 3 shows an operating waveform of the TDC circuit in FIG. 2.

FIG. 4 shows waveforms of a measurement signal and a measurement clock that are input to the TDC circuit.

FIG. 5 shows waveforms of a calibration signal and the measurement clock.

FIG. 6 is a histogram showing the result of detecting the rise of the calibration signal.

FIG. 7 shows a cumulative histogram.

FIG. 8 shows a delay conversion table.

FIG. 9 shows delay amounts before and after correction.

FIG. 10 is a characteristic diagram showing the effect of operations of the TDC apparatus.

FIG. 11 is a flowchart showing operations of the TDC apparatus.

### EXAMPLE EMBODIMENTS

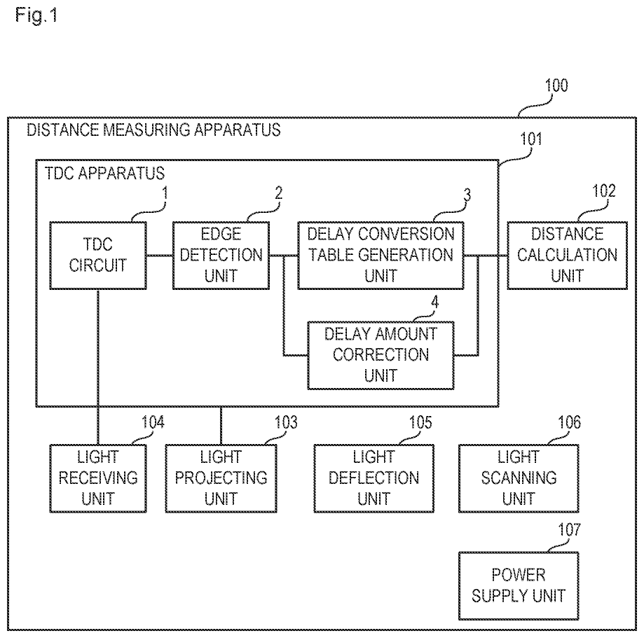

FIG. 1 is a block diagram showing a configuration of a distance measuring apparatus according to the present example embodiment.

A distance measuring apparatus 100 according to the present example embodiment emits measurement light, receives reflected light resulting from the measurement light being reflected by an object, and calculates the distance to the object based on the reception timing of the reflected light. The distance measuring apparatus 100 is provided with a TDC apparatus 101, a distance calculation unit 102, a light projecting unit 103, a light receiving unit 104, a light deflection unit 105, a light scanning unit 106, and a power supply unit 107.

The light projecting unit 103 is, for example, provided with a light source and a light source drive unit not shown. The light source is, for example, a semiconductor laser, an LED or the like. The light source drive unit is a circuit that drives light emission of the light source. The light projecting unit 103 emits measurement light toward a reflective part of the light deflection unit 105 described later. The measurement light is pulsed light having a pulse width from several nanoseconds to several tens of nanoseconds, for example.

The light deflection unit 105 disposes a reflective part such as a mirror and causes the measurement light from the light projecting unit 103 that is incident on the reflective part to be deflected in a predetermined direction. The light scanning unit 106 causes the measurement light deflected by the light deflection unit 105 to be scanned in a predetermined direction such as the horizontal or vertical direction, for example. Note that the distance measuring apparatus 100 may be configured to include only one of the light deflection unit 105 or the light scanning unit 106.

The light receiving unit 104 is, for example, provided with a light receiving element such as an avalanche photodiode, receives the reflected light of the measurement light reflected by the object, and converts the light intensity of the received reflected light into an electrical signal. When reflected light is received, the light receiving unit 104 outputs an electrical signal (hereinafter, measurement signal) related to the reflected light to the TDC apparatus 101.

The TDC apparatus 101 measures the time difference between the measurement light and the reflected light from the time that the light projecting unit 103 emits the measurement light to the time that the light receiving unit 104 receives the reflected light. The TDC apparatus 101 will be described in detail later.

The distance calculation unit 102 calculates the distance to the object from the time difference between the measurement light and the reflected light measured by the TDC apparatus 101. The distance calculation unit 102 is, for example, realized by the CPU executing a program. The technique for calculating the distance based on the time difference between the measurement light and the reflected light is called a ToF (Time-of-Flight) method, and a distance d to the object is calculated by the following equation. Here, C is the velocity of light and ΔT is the time difference between the measurement light and the reflected

d=(½)×C×ΔT

The power supply unit 107 outputs a predetermined supply voltage to the TDC apparatus 101, distance calculation unit 102, light projecting unit 103, light receiving unit 104, light deflection unit 105 and light scanning unit 106 that are provided in the distance measuring apparatus 100 to supply power for the respective units to operate. Note that the power supply unit 107 may be provided with an input terminal to which power is supplied from outside the distance measuring apparatus 100.

The TDC apparatus 101 measures the time difference between the measurement light and the reflected light as a delay time from the time that a measurement start signal corresponding to the measurement light is input until the time that the measurement signal corresponding to the reflected light is detected. Hereinafter, the TDC apparatus 101 will be described.

The TDC apparatus 101 of the present example embodiment is provided with a TDC circuit 1, an edge detection unit 2, a delay conversion table generation unit 3, and a delay amount correction unit 4. These units may be configured by dedicated hardware, and constituent elements realizable by software may be realized by a CPU executing a program.

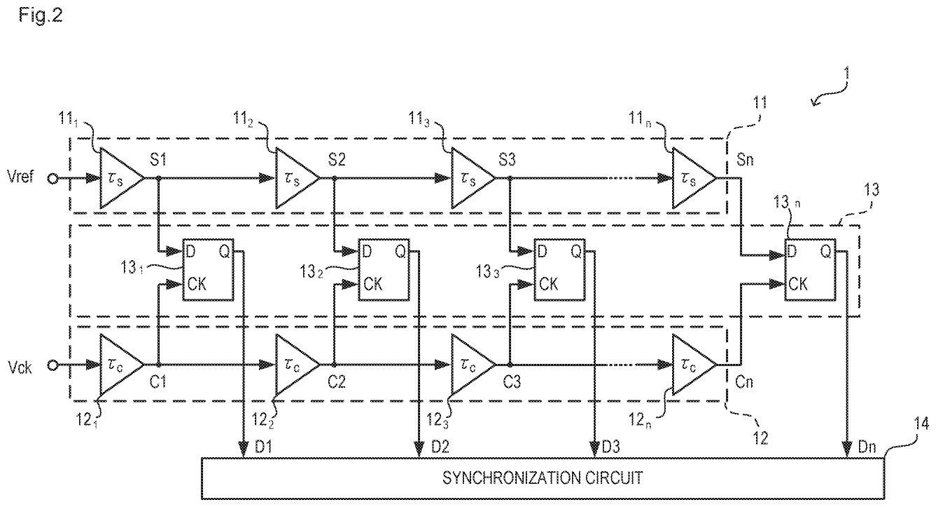

FIG. 2 shows the TDC circuit 1. The TDC1 shown in FIG. 2 is a so-called vernier TDC circuit, The TDC circuit 1 is constituted by a first delay circuit 11, a second delay circuit 12, a flip-flop array 13, and a synchronization circuit 14. Note that the TDC circuit 1 may also be a flash TDC circuit that is not be provided with the second delay circuit 12. The flip-flop array 13 is an example of a memory element capable of high-speed operation.

In the first delay circuit 11, a measurement signal is input to an input terminal Vref. The measurement signal is the signal of reflected light received by the light receiving unit 104 that results from light emitted by the light projecting unit 103 being reflected by an object. The first delay circuit 11 is constituted by n stages of delay elements 11ₙ (where n is an integer of 1 or more). The delay amount (also referred to as delay time) of each delay element 11ₙ is set to τ_{S}. The respective output nodes of the delay elements 11ₙ are represented by S1, S2, S3, . . . , Sn.

In the second delay circuit 12, a measurement clock is input to an input terminal Vck. The measurement clock is for detecting the time difference between the measurement light and the reflected light. The light projecting unit 103 emits measurement light at the timing of the rise of the measurement clock. The second delay circuit 12 is constituted by n stages of delay elements 12ₙ, similarly to the first delay circuit 11. The delay amount of each delay element 12ₙ is set to τ_{C} (<τ_{S}). The respective output nodes of the delay elements 12ₙ are represented by C1, C2, C3, . . . , Cn.

A set of output terminals is connected to a flip-flop described later, for each set of a delay element 11ₙ and a delay element 12ₙ such as the set of the delay element 11₁ and the delay element 12₁, the set of the delay element 11₂ and the delay element 12₂, and so on. Hereinafter, the delay element 11ₙ and the delay element 12ₙ will be referred to as an nth stage of delay elements, such that the delay element 11₁ and the delay element 12₁ are the first stage of delay elements, the delay element 11₂ and the delay element 12₂ are the second stage of delay elements, and so on.

The flip-flop array 13 is provided with n D flip-flops (hereinafter, referred to as D-FF) 13ₙ (where n is an integer of 1 or more). In the present example embodiment, a D-FT 13₁ is provided in correspondence with the delay element of the first stage, and a D-FF 13ₙ is provided in correspondence with the delay element of the nth stage. Specifically, an output node Sn of the delay element 11ₙ is connected to a D terminal of the D-FF 13ₙ, and an output node Cn of the delay element 12ₙ is connected to a CK terminal. Also, a Q terminal of the D-FF 13ₙ is connected to the synchronization circuit 14. The respective output nodes of the D-FFs 13ₙ are represented by D1, D2, D3, . . . , Dn.

The synchronization circuit 14 outputs the output values of the D-FFs 13₁ to 13ₙ in synchronization with the measurement clock.

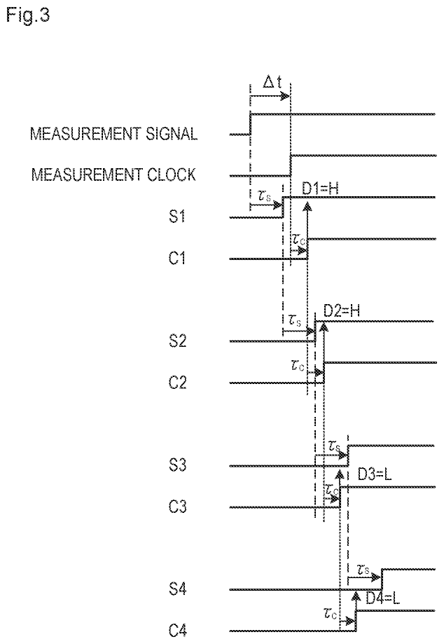

FIG. 3 shows operating waveforms of the TDC circuit 1 in FIG. 2. In this example, the measurement clock from the input terminal Vck rises from L level (hereinafter, L) to H level (hereinafter, H) after being delayed by a time difference Δt with respect to the rise of the measurement signal from the input terminal Vref from L to H. In the example shown in FIG. 3, “H, H, L, L” is obtained as data in the output nodes D1 to D4 of the D-FFs 13₁ to 13₄.

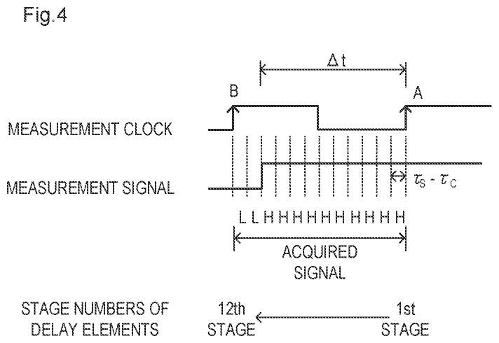

When the measurement signal and the measurement clock are input to the TDC circuit 1, the edge detection unit 2 detects the rise or fall of the measurement signal, based on the output value from the synchronization circuit 14. Here, in the present example embodiment, the TDC circuit 1 in FIG. 2 is constituted by 12 stages of delay elements (i.e., n=12) and 12 stages of the D-FFs 13₁ to 13₁₂. In this case, as described with FIG. 3, a measurement signal and a measurement clock such as shown in FIG. 4 are input, such that “H, H, H, H, H, H, H, H, H, H, L, L,” is obtained as data in the output nodes D1 to D12 of the D-FFs 13₁ to 13₁₂.

FIG. 4 shows waveforms of the measurement signal and the measurement clock that are input to the TDC circuit 1. The edge detection unit 2 detects the rise of the measurement signal, by the change of H and L of a signal input thereto. Due to the edge detection unit 2 detecting this rise, the TDC apparatus 101 can find out the stage numbers of the delay elements that detected H in the period from when the measurement signal rises until when a measurement clock A rises. That is, the TDC apparatus 101 can find out the time interval from when the measurement signal rises until when the measurement clock A rises. The time interval is derived by the product of the delay amounts (τ_{S}-τ_{C}) (also referred to as the time resolution) of the delay elements and the stage numbers of the delay elements. The TDC apparatus 101 can thereby find out the time interval from the rise (or fall) of a measurement clock B immediately previous to the measurement clock A to the rise (or fall) of the measurement signal.

The delay conversion table generation unit 3 generates a delay conversion table. The delay amount (τ_{S}-τ_{C}) of each delay element varies under the influence of variation in the manufacturing process. The delay conversion table is for calibrating a delay amount that is based on (τ_{S}-τ_{C}) which is variable. More specifically, the delay conversion table shows the relationship between the detection stage of each delay element that detects the rising (or falling) edge of a calibration signal described later and the cumulative delay amount of the delay elements up to that detection stage, when the calibration signal is input to the TDC circuit 1. Hereinafter, the operation for generating the delay conversion table will be referred to as a calibration operation. The delay conversion table generation unit 3 performs the calibration operation at the timing at which the distance measuring apparatus 100 is not performing the distance measurement operation, that is, at the timing at which the measurement signal is not input to the TDC circuit 1.

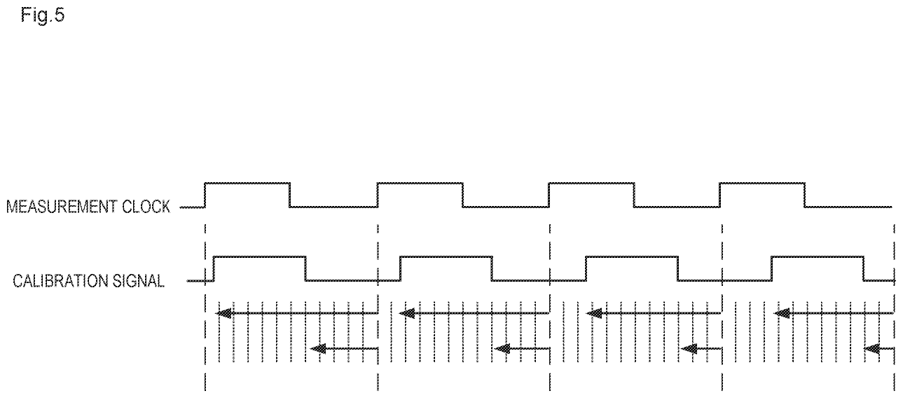

FIG. 5 shows waveforms of the calibration signal and the measurement clock. In the calibration operation, the delay conversion table generation unit 3 inputs the calibration signal from a clock generation circuit not shown to the input terminal Vref (see FIG. 2). The measurement clock is input to the input terminal Vck. The calibration signal has a period close to the period of the measurement clock and is not in synchronization with the measurement clock. The period of the calibration signal is variable, and the difference between the period of the calibration signal and the period of the measurement clock preferably diverges from the time resolution (τ_{S}-τ_{C}) of the TDC circuit 1. For example, if the time resolution of the TDC circuit 1 is 10 [ps], the period of the calibration signal when the period of the measurement clock is 4 [ns] is preferably set in a range from larger than 4 [ns] to smaller than 4.016 [ns].

When the calibration signal is input, the delay conversion table generation unit 3, as shown in FIG. 5, counts the number of rises and the number of falls of the detected calibration signal, for each stage (12 stages in FIG. 5) of the delay elements in the TDC circuit 1.

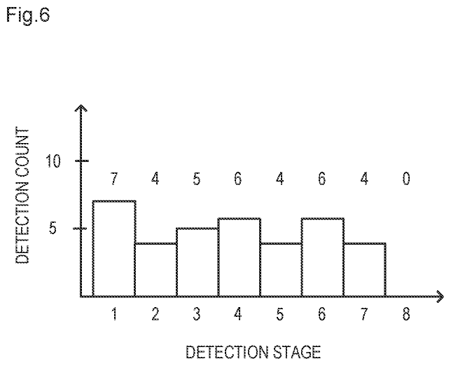

FIG. 6 is a histogram showing the result of detecting the rise of the calibration signal. The delay conversion table generation unit 3 generates a histogram showing the result of detecting the rise of the calibration signal. FIG. 6 shows the result of inputting the calibration signal, such that the total number of rises of the calibration signal (hereinafter, total detection count) that are detected by the delay elements of the respective stages is “36”. In FIG. 6, the number of rises of the calibration signal (hereinafter, detection count) detected by the delay element of the first stage is “7”. The detection count in the eighth stage is “0”. The detection count represents the delay amount of the delay element of each stage. For example, when the period of the measurement clock is 4 [ns], the total detection count “36” corresponds to the period 4 [ns] of that measurement clock. Thus, the delay amount of the delay element of the first stage will be 7/36×4 [ns].

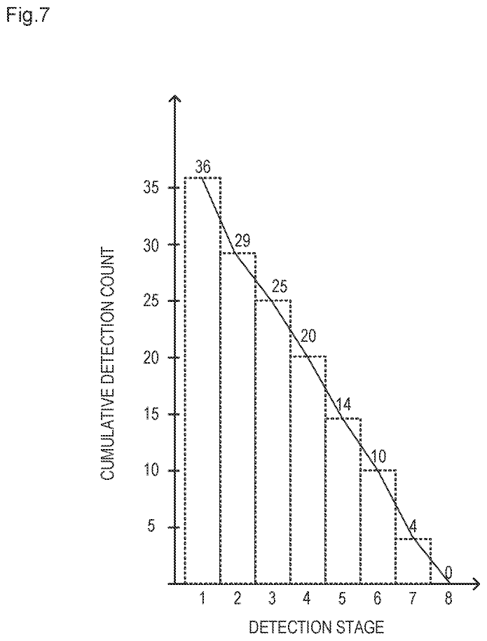

Next, the delay conversion table generation unit 3 generates a cumulative histogram from the histogram shown in FIG. 6, in order to estimate the cumulative delay amount of the delay elements up to each stage. FIG. 7 shows a cumulative histogram. This cumulative histogram in FIG. 7 is generated by performing a calculation that involves adding the detection count of the eighth stage which is the last stage to the detection count of the seventh stage, adding the added detection count of the seventh stage to the detection count of the sixth stage, and so on in order from the delay element of the last stage to the delay element of the first stage in the histogram in FIG. 6, Note that the result obtained by the above calculation will be referred to as the cumulative detection count (vertical axis in FIG. 7).

The reason for performing cumulative processing from the delay element of the last stage to the delay element of the first stage is as follows. The delay amount 7/36×4 [ns] of the delay element of the first stage represented in FIG. 6 is the delay amount from when the measurement signal rises in the delay element of the first stage until when the measurement clock A rises in FIG. 4. The distance measurement calculation requires the delay amount from the measurement clock B immediately previous to the measurement clock A until when the measurement signal rises in the delay element of the first stage in FIG. 4. The delay amount from the measurement clock B is the cumulative delay amount of the delay elements from the delay element that detected the rise of the measurement signal to the delay element of the last stage.

In view of this, cumulative processing for accumulating the delay amounts from the delay element of the last stage to the delay element of the first stage in order is performed. The time interval from the measurement clock B to the rise of the measurement signal can thereby be calculated. This time interval can be calculated with the cumulative delay amount up to the stage of the delay element that detected the rise of the measurement signal, and can be calculated as (cumulative detection count)/(total detection count)×(period of measurement clock). For example, if the period of the measurement clock is 4 [ns] and the rise of the measurement signal is detected by the delay element of the first stage, the cumulative delay amount of the delay elements from the measurement clock B immediately previous to the measurement clock A to the first stage in FIG. 4 is 36/36×4 [ns]=4 [ns].

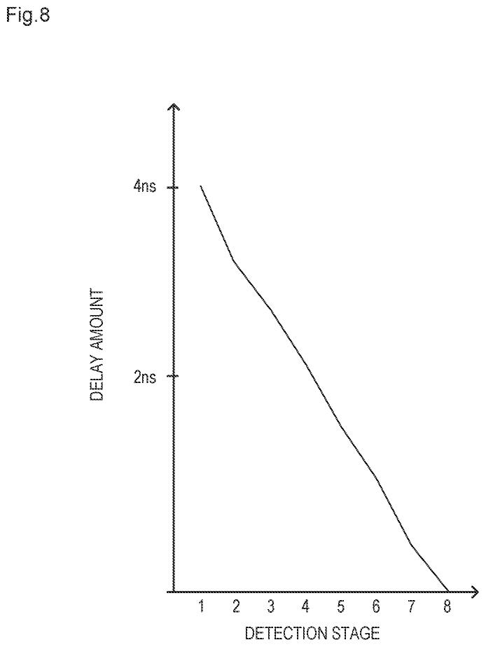

FIG. 8 shows a delay conversion table. The delay conversion table generation unit 3 generates a table in which the cumulative detection counts on the vertical axis of the cumulative histogram shown in FIG. 7 are converted into delay amounts. This table will be referred to as a delay conversion table. FIG. 8 shows a delay conversion table in the case where the period of the measurement clock is 4 [ns]. By using the delay amount corresponding to the stage of the delay element that is obtained from the delay conversion table instead of delay amount (τ_{S}-τ_{C})×detection stage number when the distance measuring apparatus 100 performs the distance measurement operation, the time interval of the measurement signal and the measurement clock B can be derived, as described with FIG. 4.

The delay conversion table generation unit 3 generates the delay conversion table shown in FIG. 8 for both the rise and the fall of the calibration signal.

The delay amount correction unit 4 corrects the delay conversion table generated by the delay conversion table generation unit 3. As mentioned above, the voltage drop of the supply voltage of the TDC circuit 1 during the calibration operation is larger than during the measurement operation. When the voltage drop is large, the delay amount of the delay element of each stage becomes larger than at the time of a predetermined supply voltage, and the position of the stage number corresponding to the period length of the measurement clock, that is, the maximum stage number of the delay conversion table, decreases. The maximum stage number is the stage number of the final stage of the delay elements that were able to detect the calibration signal. In view of this, the delay amount correction unit 4 performs correction for increasing the maximum stage number of the delay conversion table.

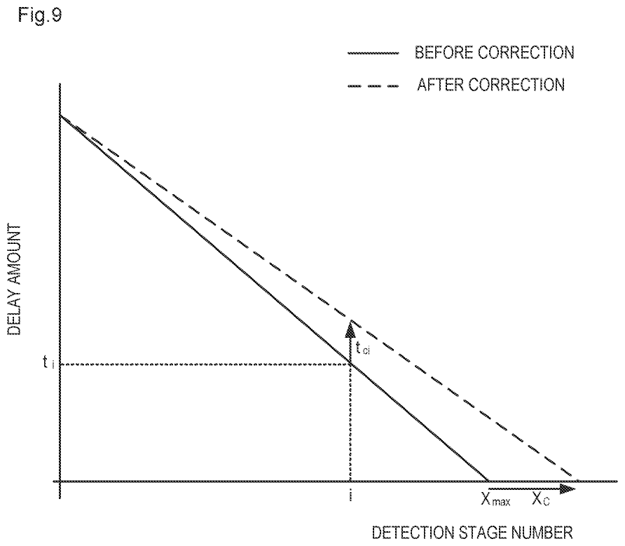

FIG. 9 shows delay amounts before and after correction. Specifically, as shown in FIG. 9, the delay amount correction unit 4 adds a predetermined correction stage number X_{C} to a maximum stage number Xₘₐₓ of the delay conversion table generated by the calibration operation, and determines the delay amount to be corrected. X_{C} is, for example, determined from the maximum number of stages in which edges are detected from the reflected light of an object resulting from actual implementation of a measurement operation in advance. In the measurement operation in this case, the position of the object from which the measurement light is reflected is manipulated, such that the detection stage number changes successively. In order to generate a delay amount obtained by adding the correction stage number X_{C} to the maximum stage number Xₘₐₓ, the delay amount correction unit 4 adds a correction delay amount t_{ci} to a cumulative delay amount tᵢ corresponding to the delay element of an ith stage. The correction delay amount t_{ci} is derived by the following equation.

$${t}_{ci} = \{ \begin{matrix}{t}_{i} \times ( - \frac{{x}_{c}}{{x}_{max} + {x}_{c}} ) + {t}_{offset} , & i < {x}_{max} \\ {t}_{offset} - {h}_{i} \times \frac{{t}_{offset}}{{\sum }_{0}^{{x}_{c}} {h}_{i}} , & i = {x}_{max} \\ {t}_{c ( i - 1 )} - {h}_{i} \times \frac{{t}_{offset}}{{\sum }_{0}^{{x}_{c}} {h}_{i}} , & i > {x}_{max}\end{matrix} , {t}_{offset} = \frac{N \times {x}_{c}}{{x}_{max} + {x}_{c}} \qquad [ Equation 1 ]$$

Here, hᵢ is the detection count (histogram value in FIG. 6) in which the rise (or fall) of the calibration signal is detected by the delay element of the ith stage, Xₘₐₓ is the maximum stage number of the delay conversion table prior to correction, and X_{C} is the predetermined correction stage number. Also, N is the total detection count of the calibration signal, and is changed as appropriate according to the calibration signal that is input to the TDC circuit 1.

The delay amount correction unit 4 may perform correction of the delay amount of the delay conversion table every time the delay conversion table is generated, or may perform correction under predetermined conditions. For example, the delay amount correction unit 4 holds the maximum stage number of the delay conversion table generated in the initial calibration operation. The delay amount correction unit 4 compares the maximum stage number of the delay conversion table generated in the calibration operation performed a second time with the maximum stage number that is held. If the difference between the two maximum stage numbers that are compared exceeds a predetermined value, the delay amount correction unit 4 corrects the delay conversion table generated in the calibration operation performed the second time. The delay amount correction unit 4 holds the maximum stage number of the corrected delay conversion table, and compares this maximum stage number with the maximum stage number of the delay conversion table generated in the calibration operation performed next time. If the difference between the two maximum stage numbers that are compared exceeds the predetermined value, the delay amount correction unit 4 corrects the delay conversion table generated in the calibration operation performed a third time. On the other hand, in the case where the delay conversion table generated in the calibration operation performed the second time is not corrected, the delay amount correction unit 4 compares the maximum stage number of the delay conversion table generated by the calibration initially performed with the maximum stage number of the delay conversion table generated in the calibration operation performed the third time. Thereafter, this operation is repeated.

The TDC apparatus 101 measures the time difference between the measurement light and the reflected light using the delay conversion table corrected in this way. For example, if the stage number in which the rise of the measurement signal is detected is “4”, the TDC apparatus 101 acquires the cumulative delay amount corresponding to the stage number “4” from the table in FIG. 8 and acquires the time interval from the measurement clock B (see FIG. 4). The TDC apparatus 101 then calculates the time difference between the measurement light and the reflected light from the number of clocks of the measurement clock up to the measurement clock B after emitting the measurement light and the acquired time interval. The distance calculation unit 102 then performs a calculation for deriving the distance to the object, based on the time difference measured by the TDC apparatus 101 and the velocity of light

In this way, even when a delay conversion table is generated in which the maximum stage number is reduced due to the voltage drop of the supply voltage during the calibration operation, the influence of the voltage drop can be avoided by correcting the maximum stage number of that delay conversion table. Measurement accuracy during the distance measurement operation can then be improved, by using the corrected delay conversion table.

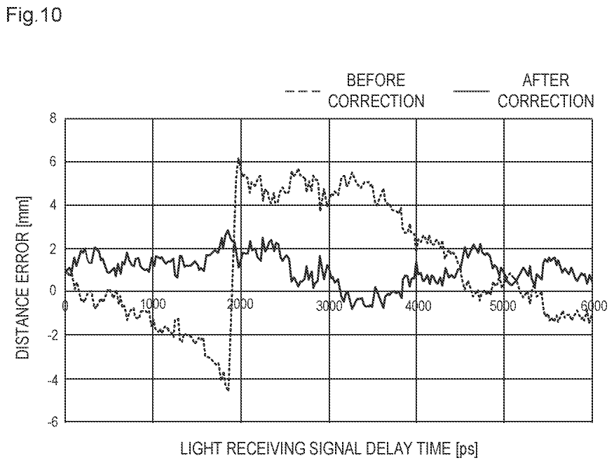

FIG. 10 is a characteristic diagram showing the effect of the operations of the TDC apparatus 101. Light receiving signal delay time is taken on the horizontal axis, and measurement distance error in the case where the light receiving signal is delayed 5 psec each time is illustrated. The dashed line indicates the case before correction, with it being evident that the distance error varies greatly at around 2000 psec where the detection stages of the delay elements increase. On the other hand, the solid line indicates the case where correction according to the present example embodiment is performed, with it being evident that the variation in the distance error is reduced.

Note that the delay amount correction unit 4 may be configured to perform correction of the delay amount corresponding to the detection stage of the delay element, based on the error of the delay amount specified in each detection stage, rather than the cumulative delay amount of the delay elements up to the detection stage. Also, correction of the delay amount may be performed by subtracting the correction delay amount, rather than only in the case where the correction delay amount is added to the delay amount corresponding to the detection stage. This is because the voltage drop of the supply voltage of the TDC circuit 1 during the measurement operation can be larger than during the calibration operation, depending on the conditions.

Note that a detection echo management unit may be provided between the TDC apparatus 101 and the distance calculation unit 102. The rising edge and falling edge of a measurement signal (echo) to be detected are detected at different timings depending on the width (pulse length) of the echo. In order to smoothly perform subsequent processing, the timings of both edges are adjusted by the detection echo management unit and passed to the distance calculation unit 102 together. Also, the edges are always in order of rising edge then falling edge. Thus, this detection echo management unit holds the count of the rising edge until the falling edge is detected, and passes the respective counts to the downstream distance calculation unit 102 at a timing at which both edges have been detected. If the order of the edges is reversed, the echo is removed as a detection error.

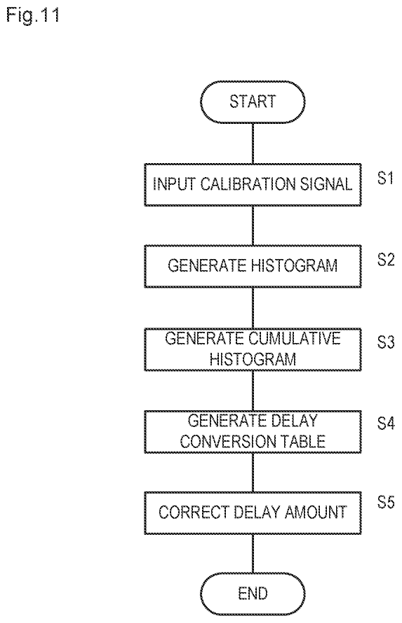

Next, operations of the TDC apparatus 101 will be described. FIG. 11 is a flowchart showing operations of the TDC apparatus 101. Note that, in the present example embodiment, a correction method is implemented by operating the TDC apparatus 101. Therefore, the following description of operations of the TDC apparatus 101 is given in place of description of the correction method in the present example embodiment.

The TDC apparatus 101 performs the calibration operation at a timing at which the distance measuring apparatus 100 is not performing the distance measurement operation. First, the TDC apparatus 101 inputs the calibration signal to the input terminal Vref of the TDC circuit 1 (S1). Next, the delay conversion table generation unit 3 generates the histogram of FIG. 6 (S2), and generates the cumulative histogram shown in FIG. 7 from the generated histogram (S3). Thereafter, the delay conversion table generation unit 3 generates the delay conversion table shown in FIG. 8 (S4).

The delay amount correction unit 4 then corrects the delay amount, by adding a predetermined stage number to the maximum stage number of the delay elements in the delay conversion table (S5). The specific correction method is as described with FIG. 9.

### LIST OF REFERENCE SIGNS

1 TDC circuit
2 Edge detection unit
3 Delay conversion table generation unit
4 Delay amount correction unit
11 First delay circuit
12 Second delay circuit
13 Flip-flop array
14 Synchronization circuit
36 Total detection count
100 Distance measuring apparatus
101 TDC apparatus
102 Distance calculation unit
103 Light projecting unit
104 Light receiving unit
105 Light deflection unit
106 Light scanning unit
107 Power supply unit

1. A TDC apparatus comprising:
a TDC circuit having:
a delay circuit including a plurality of stages of delay elements configured to sequentially delay a measurement signal; and
a plurality of storage elements provided in correspondence with the plurality of stages of delay elements, and configured to respectively hold outputs of the plurality of stages of delay elements in response to a measurement clock input thereto;
an edge detection unit configured to detect a detection stage of a delay element, among the plurality of delay elements, that detects at least a rising edge of the measurement signal, based on switching of the outputs of the plurality of storage elements; and
a delay amount correction unit configured to output a delay time of the measurement signal whose delay amount has been corrected by adding or subtracting a correction delay amount to or from a delay amount corresponding to the detection stage of the delay element in a delay conversion table relating to the detection stage of the delay element and a delay amount of the plurality of delay elements.

2. The TDC apparatus according to claim 1, further comprising:
a delay conversion table generation unit configured to input a calibration signal whose period differs from the measurement clock to the delay circuit of the TDC circuit, and generate the delay conversion table relating to the detection stage of a delay element, among the plurality of delay elements, that detects a rising edge of the calibration signal and the delay amount of the plurality of delay elements.

3. The TDC apparatus according to claim 2,
wherein the delay amount of the delay conversion table generation unit is a cumulative delay amount of the delay elements up to each detection stage from an initial stage of the plurality of stages of delay elements.

4. The TDC apparatus according to claim 3,
wherein the delay amount correction unit corrects the delay amount by adding, to a cumulative delay amount tᵢ corresponding to the delay element of an ith stage, a correction delay amount t_{ci} calculated by the following equation:
$${t}_{ci} = \{ \begin{matrix}{t}_{i} \times ( - \frac{{x}_{c}}{{x}_{max} + {x}_{c}} ) + {t}_{offset} , & i < {x}_{max} \\ {t}_{offset} - {h}_{i} \times \frac{{t}_{offset}}{{\sum }_{0}^{{x}_{c}} {h}_{i}} , & i = {x}_{max} \\ {t}_{c ( i - 1 )} - {h}_{i} \times \frac{{t}_{offset}}{{\sum }_{0}^{{x}_{c}} {h}_{i}} , & i > {x}_{max}\end{matrix} , {t}_{offset} = \frac{N \times {x}_{c}}{{x}_{max} + {x}_{c}} \qquad [ Equation 1 ]$$
where hᵢ is a detection count in which the rise of the calibration signal is detected by the delay element of the ith stage, Xₘₐₓ is a maximum stage number of the delay elements in the delay conversion table, X_{C} is a predetermined correction stage number, and N is a total detection count in which the rise of the calibration signal is detected by the delay element of each stage.

5. A distance measuring apparatus comprising:
the TDC apparatus according to claim 1;
a light projecting unit configured to emit measurement light in synchronization with the measurement clock;
a light receiving unit configured to receive reflected light of the measurement light reflected by an object, and output a measurement signal related to the reflected light to the TDC apparatus; and
a distance calculation unit configured to calculate a distance to the object from a time difference between the measurement light and the reflected light after a delay amount is corrected in the TDC apparatus.

6. The distance measuring apparatus according to claim 5, further comprising:
at least one of a light deflection unit configured to cause the measurement light emitted from the light projecting unit to be deflected in a predetermined direction and a light scanning unit configured to cause the measurement light to be scanned in a predetermined direction.

7. A correction method in a TDC apparatus including a TDC circuit having a delay circuit including a plurality of stages of delay elements configured to sequentially delay a measurement signal and a plurality of storage elements provided in correspondence with the plurality of stages of delay elements and configured to respectively hold outputs of the plurality of stages of delay elements in response to a measurement clock input thereto, the correction method comprising:
detecting a detection stage of a delay element, among the plurality of delay elements, that detects at least a rising edge of the measurement signal, based on switching of the outputs of the plurality of storage elements; and
outputting a delay time of the measurement signal whose delay amount has been corrected by adding or subtracting a correction delay amount to or from a delay amount corresponding to the detection stage of the delay element in a delay conversion table relating to the detection stage of the delay element and a delay amount of the plurality of delay elements.
